(19) United States
(12) Patent Application Publication
(10) Pub. No.: US 2015/0060910 A1
(43) Pub. Date: Mar. 5, 2015

(54) Conductive Transparent Reflector

(71) Applicant: Intermolecular Inc., San Jose, CA (US)

(72) Inventors: Guowen Ding, San Jose, CA (US); Jianhua Hu, Palo Alto, CA (US); Minh Huu Le, San Jose, CA (US)

(73) Assignee: Intermolecular Inc., San Jose, CA (US)

(21) Appl. No.: 14/014,029

(22) Filed: Aug. 29, 2013

(51) Int. Cl. H01L 33/46; H01L 33/42

(52) U.S. Cl. CPC H01L 33/46; H01L 33/42
USPC 257/98; 438/29

(57) ABSTRACT

Methods to improve the reflection of light emitting devices are disclosed. A method consistent with the present disclosure includes forming a light generating layer over a site-isolated region of a substrate. Next, forming a first transparent conductive layer over the light generating layer. Forming a low refractive index material over the first transparent conductive layer, and in time, forming a second transparent conductive layer over the low refractive index material. Subsequently, forming a reflective material layer thereon. Accordingly, methods consistent with the present disclosure may form a plurality of light emitting devices in various site-isolated regions on a substrate.

### FIELD

The present disclosure relates to improving performance of light emitting diodes (LEDs).

### BACKGROUND

Reflecting electrodes are currently used in various LED and other light emitting devices. Reflection is such an important metric that various techniques have been explored to maximize this metric in reflecting electrodes to increase device performance.

For example, numerous techniques have been attempted to integrate multiple layers with alternate high/low/high refractive indices within these devices (e.g., distributed Bragg reflectors—DBRs). However, the scalability of DBRs and other similar devices are limited in the reflecting electrodes because the electrical requirements in LEDs render only a few materials suitable to employ this technique.

Moreover, since Indium-Tin-Oxide (ITO) is ubiquitous in photovoltaic devices (e.g., within TOO), identifying materials with significantly lower refractive indices to successfully employ the high/low/high refractive indices technique poses a challenge.

Accordingly, an effective method to enhance reflection for electrodes within light emitting devices is desired. The present disclosure addresses such a need.

### SUMMARY OF THE DISCLOSURE

The following summary is included in order to provide a basic understanding of some aspects and features of the present disclosure. This summary is not an extensive overview of the disclosure and as such it is not intended to particularly identify key or critical elements of the disclosure or to delineate the scope of the disclosure. Its sole purpose is to present some concepts of the disclosure in a simplified form as a prelude to the more detailed description that is presented below.

Methods to improve the reflection of light emitting devices are disclosed. A method consistent with the present disclosure includes forming a light generating layer over a site-isolated region of a substrate. Next, forming a first transparent conductive layer over the light generating layer. Forming a low refractive index material over the first transparent conductive layer, and in time, forming a second transparent conductive layer over the low refractive index material. Subsequently, forming a reflective material layer thereon. Accordingly, methods consistent with the present disclosure may form a plurality of light emitting devices in various site-isolated regions on a substrate.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale. The techniques of the present disclosure may readily be understood by considering the following detailed description in conjunction with the accompanying drawings, in which:

FIG. 1 is a schematic diagram for implementing combinatorial processing.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 is a simplified schematic diagram illustrating a light emitting device consistent with the present disclosure.

FIG. 5 is a simplified schematic diagram illustrating a three dimensional plot displaying the reflectance achieved for various thickness values of first and second transparent conductive layers.

FIG. 6 is a simplified schematic diagram illustrating a combinatorial PVD system according to some embodiments described herein.

FIG. 7 is a simplified schematic diagram illustrating a substrate that has been processed in a combinatorial manner.

FIG. 8 illustrates a pattern of site-isolated regions of a substrate.

FIG. 9 is a flowchart of a method to form a light emitting device consistent with the present disclosure.

FIGS. 10A-10E are illustrations of an exemplary sequence for forming a light emitting device consistent with the present disclosure.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to some embodiments have not been described in detail to avoid unnecessarily obscuring the description.

It is to be understood that unless otherwise indicated this disclosure is not limited to specific layer compositions or surface treatments. It is also to be understood that the terminology used herein is for the purpose of describing particular embodiments only and is not intended to limit the scope of the present disclosure.

It must be noted that as used herein and in the claims, the singular forms “a,” and “the” include plural referents unless the context clearly dictates otherwise. Thus, for example, reference to “a layer” also includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” as used herein refers to a localized area on a substrate which is, was, or is intended to be used for processing or formation of a selected material. The region may include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, coated silicon, other semiconductor materials, glass, polymers, metal foils, sapphire, aluminum oxide, etc. The term “substrate” or “wafer” may be used interchangeably herein. Semiconductor wafer shapes and sizes may vary and include commonly used round wafers of 2″, 4″, 200 mm, or 300 mm in diameter.

It is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single substrate without the need of consuming the equivalent number of monolithic substrates per material(s), processing condition(s), sequence(s) of processing conditions, sequence(s) of processes, and combinations thereof. This may greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006; U.S. Pat. No. 7,824,935 filed on Jul. 2, 2008; U.S. Pat. No. 7,871,928 filed on May 4, 2009; U.S. Pat. No. 7,902,063 filed on Feb. 10, 2006; and U.S. Pat. No. 7,947,531 filed on Aug. 28, 2009 which are all herein incorporated by reference for all purposes.

Systems and methods for HPC™ processing are further described in U.S. Pat. No. 8,084,400 filed on Feb. 10, 2006, claiming priority from Oct. 15, 2005; U.S. Patent Application No. 2007/0267631 filed on May 18, 2006, claiming priority from Oct. 15, 2005; U.S. Patent Application No. 2007/0202614 filed on Feb. 12, 2007, claiming priority from Oct. 15, 2005; U.S. Patent Application No. 2013/0065355 filed on Sep. 12, 2011, and U.S. Patent Application No. 2007/0202610 filed on Feb. 12, 2007, claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

In addition, systems and methods for combinatorial processing are further described in U.S. Patent Application No. 2013/0168231 filed on Dec. 31, 2011 and U.S. Patent Application No. 2013/0130490 filed on Nov. 22, 2011 which are all herein incorporated by reference for all purposes.

HPC™ processing techniques have been adapted to the development and investigation of absorber layers and buffer layers for TFPV solar cells as described in U.S. Patent Application No. 2013/0071966 filed on Sep. 19, 2011, entitled “COMBINATORIAL METHODS FOR DEVELOPING SUPERSTRATE THIN FILM SOLAR CELLS” and is incorporated herein by reference for all purposes.

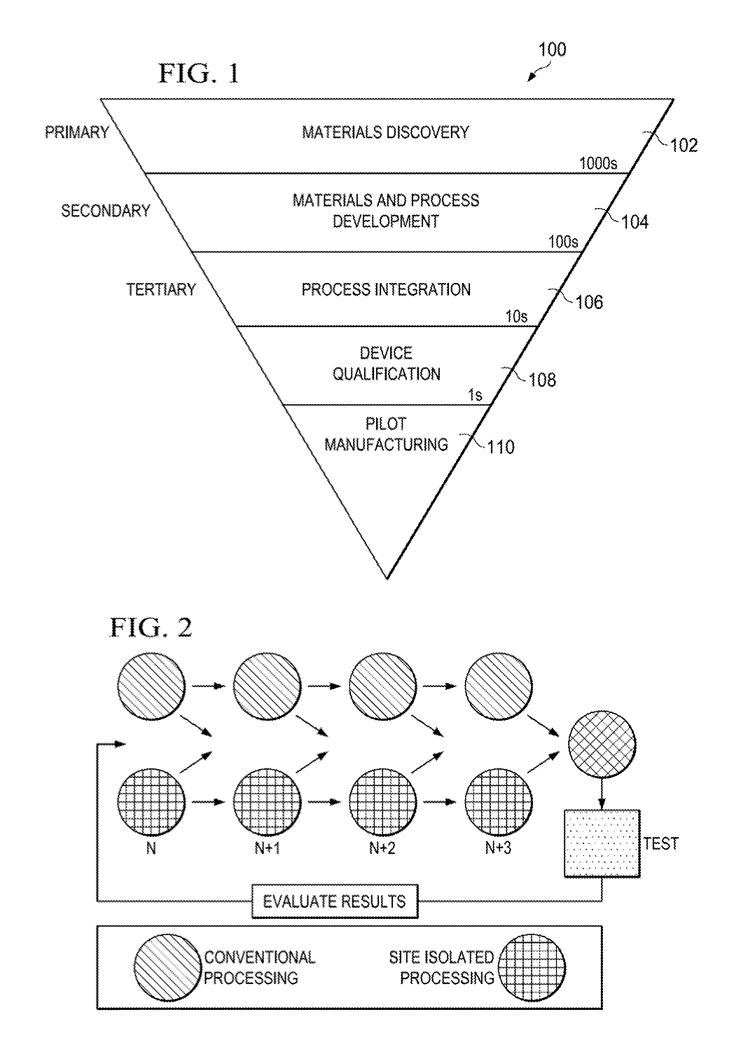

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages may be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106 where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes may proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from HPC™ techniques described in U.S. Patent Application No. 2007/0202610 filed on Feb. 12, 2007 which is hereby incorporated for reference for all purposes. Portions of the '137 application have been reproduced below to enhance the understanding of the present disclosure.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete site-isolated region. Furthermore, while different materials or unit processes may be used for corresponding layers or steps in the formation of a structure in different site-isolated regions of the substrate during the combinatorial processing, the application of each layer or use of a given unit process is substantially consistent or uniform throughout the different site-isolated regions in which it is intentionally applied. Thus, the processing is uniform within a site-isolated region (inter-region uniformity) and between site-isolated regions (intra-region uniformity), as desired. It should be noted that the process may be varied between site-isolated regions, for example, where a thickness of a layer is varied or a material may be varied between the site-isolated regions, etc., as desired by the design of the experiment.

The result is a series of site-isolated regions on the substrate that contain structures or unit process sequences that have been uniformly applied within that site-isolated region and, as applicable, across different site-isolated regions. This process uniformity allows comparison of the properties within and across the different site-isolated regions such that the variations in test results are due to the varied parameter (e.g., materials, unit processes, unit process parameters, hardware details, or process sequences) and not the lack of process uniformity. In the embodiments described herein, the positions of the discrete site-isolated regions on the substrate may be defined as needed, but are preferably systematized for ease of tooling and design of experimentation. In addition, the number, variants and location of structures within each site-isolated region are designed to enable valid statistical analysis of the test results within each site-isolated region and across site-isolated regions to be performed.

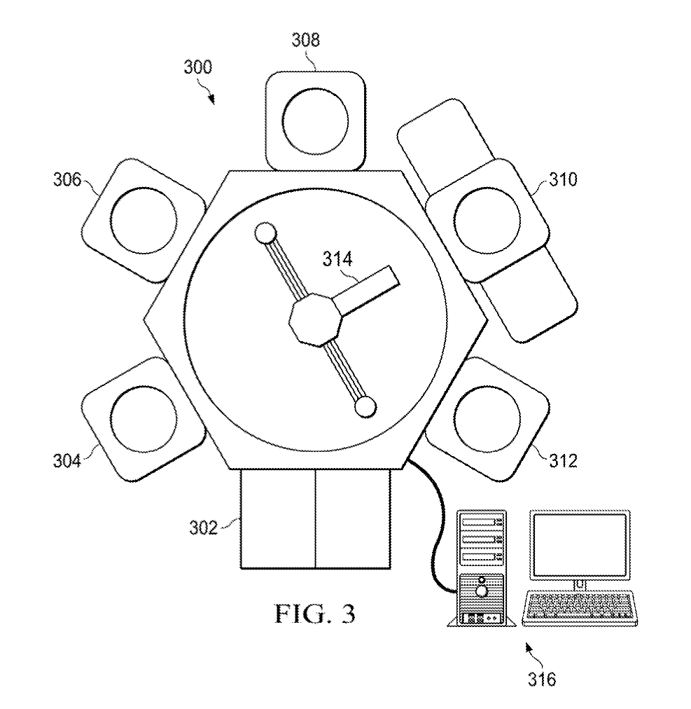

FIG. 2 is a simplified schematic diagram illustrating a general methodology for combinatorial process sequence integration that includes site-isolated processing and/or conventional processing. In some embodiments, the substrate is initially processed using conventional process N. In some exemplary embodiments, the substrate is then processed using site-isolated process N+1. During site-isolated processing, an HPC™ module may be used, such as the HPC module described in U.S. Pat. No. 8,084,400 filed on Feb. 10, 2006, which is incorporated herein by reference for all purposes. The substrate may then be processed using site-isolated process N+2, and thereafter processed using conventional process N+3. Testing is performed and the results are evaluated. The testing may include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site-isolated processing for either process N or N+3. For example, a next process sequence may include processing the substrate using site isolated process N, conventional processing for processes N+1, N+2, and N+3, with testing performed thereafter.

It should be appreciated that various other combinations of conventional and combinatorial processes may be included in the processing sequence with regard to FIG. 2. That is, the combinatorial process sequence integration may be applied to any desired segments and/or portions of an overall process flow. Characterization, including physical, chemical, acoustic, magnetic, electrical, optical, etc. testing, may be performed after each process operation, and/or series of process operations within the process flow as desired. The feedback provided by the testing is used to select certain materials, processes, process conditions, and process sequences and eliminate others. Furthermore, the above flows may be applied to entire monolithic substrates, or portions of monolithic substrates such as coupons.

Under combinatorial processing operations the processing conditions at different site-isolated regions may be controlled independently. Consequently, process material amounts, reactant species, processing temperatures, processing times, processing pressures, processing flow rates, processing powers, processing reactant compositions, the rates at which the reactions are quenched, deposition order of process materials, process sequence steps, hardware details, etc., may be varied from site-isolated region to site-isolated region on the substrate. Thus, for example, when exploring materials, a processing material delivered to a first and second site-isolated region may be the same or different. If the processing material delivered to the first site-isolated region is the same as the processing material delivered to the second isolated-region, this processing material may be offered to the first and second site-isolated regions on the substrate at different concentrations. In addition, the material may be deposited under different processing parameters. Parameters which may be varied include, but are not limited to, process material amounts, reactant species, processing temperatures, processing times, processing pressures, processing flow rates, processing powers, processing reactant compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used may be varied.

As mentioned above, within a site-isolated region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the site-isolated regions. It should be appreciated that a site-isolated region may be formed on another site-isolated region in some embodiments or the site-isolated regions may be isolated and, therefore, non-overlapping. When the site-isolated regions are adjacent, there may be a slight overlap wherein the materials or precise process interactions are not known, however, a portion of the site-isolated regions, normally at least 50% or more of the area, is uniform and all testing occurs within that site-isolated region. Further, the potential overlap is only allowed with material of processes that will not adversely affect the result of the tests. Both types of site-isolated regions are referred to herein as site-isolated regions or discrete site-isolated regions.

Substrates may be a conventional round 200 mm, 300 mm, or any other larger or smaller substrate/wafer size. In some embodiments, substrates may be square, rectangular, or any other shape. One skilled in the art may appreciate that the substrate may be a blanket substrate, a coupon (e.g., partial wafer), or even a patterned substrate having predefined site-isolated regions. In some other embodiments, a substrate may have site-isolated regions defined through the processing described herein.

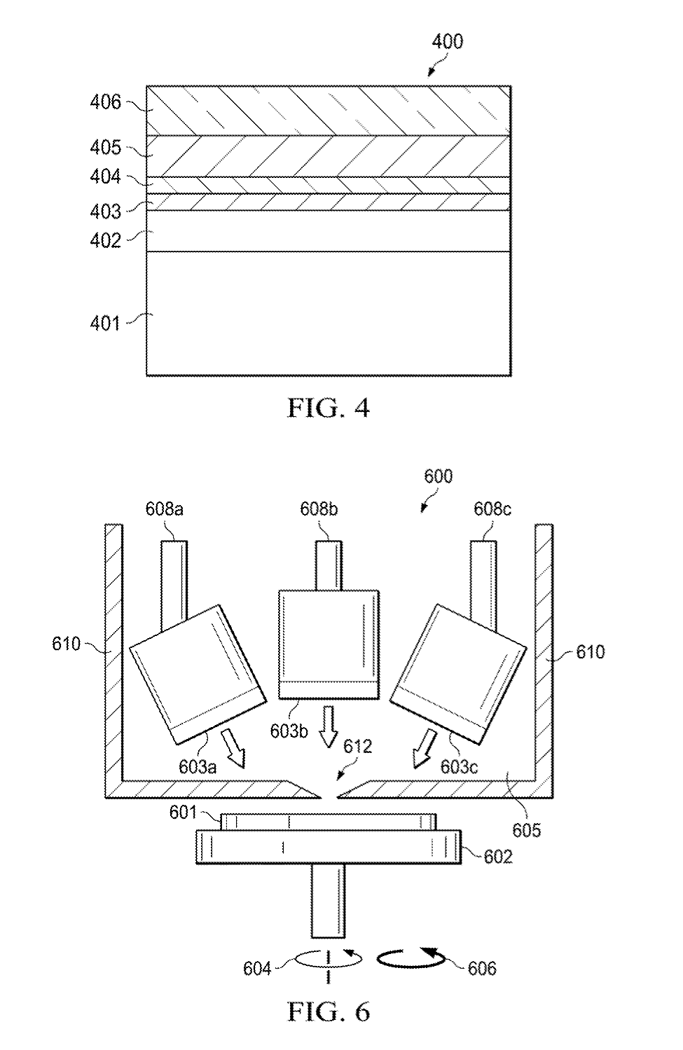

FIG. 3 is a simplified schematic diagram illustrating a HPC system. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that may be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. Patent Application No. 2008/0017109 and U.S. Pat. No. 7,867,904, the entire disclosures of which are herein incorporated by reference for all purposes. In a HPC system, a plurality of methods may be employed to deposit material upon a substrate employing combinatorial processes.

Methods to improve the reflection of light emitting devices are disclosed. A method consistent with the present disclosure includes forming a light generating layer over a site-isolated region of a substrate. Next, forming a first transparent conductive layer over the light generating layer. Forming a low refractive index material over the first transparent conductive layer, and in time, forming a second transparent conductive layer over the low refractive index material. Subsequently, forming a reflective material layer thereon. Accordingly, methods consistent with the present disclosure may form a plurality of light emitting devices in various site-isolated regions on a substrate.

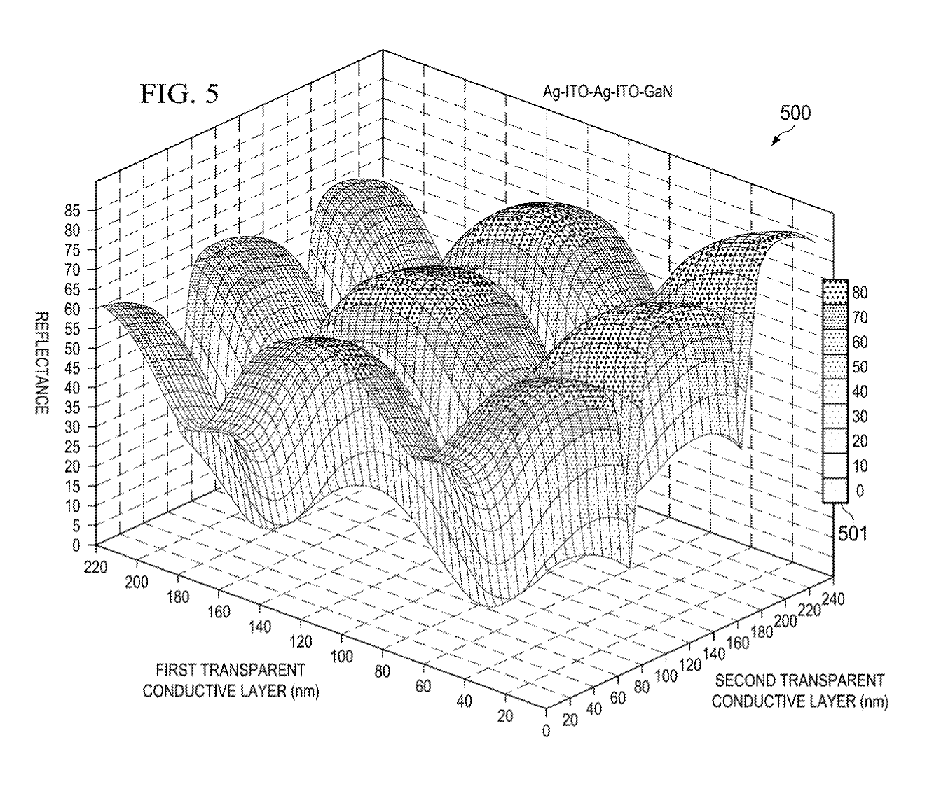

FIG. 4 is a simplified schematic diagram illustrating a light emitting device 400 consistent with the present disclosure. As shown, light emitting device 400 includes a plurality of layers which collectively generates and emits light therefrom. In some embodiments, light emitting device 400 may include a LED device.

As shown in the figure, light emitting device 400 includes a substrate 401 which has multiple layers disposed thereon. Substrate 401 may comprise sapphire, aluminum oxide (Al₂O₃), or any other suitable material. In some embodiments, substrate 401 comprises a sapphire material which provides excellent electrical insulation for the device 400. Moreover, substrate 401 effectively dissipates heat from the device 400 during operation.

Further, substrate 401 may provide a non-conducting base for a light generating layer 402 to be formed (e.g., grown) thereon. In some embodiments, light generating material layer 402 may comprise semiconductor material(s) such as Gallium Nitride (GaN) (p or n doped). Further, light generating material 402 may have a thickness in the range of 250-400 nm. In some embodiments, light generating material 402 has a thickness of approximately 300 nm.

FIG. 4 further illustrates a first transparent conductive layer 403 disposed over light generating material 402. As shown, first transparent conductive layer 403 may be formed directly upon the light generating material 402.

In some embodiments, first transparent conductive layer 403 comprises an ITO material. The thickness of first transparent conductive layer 403 may range from approximately 5-25 nm. In some embodiments, the thickness of first transparent conductive layer 403 is approximately 5 nm.

In some embodiments, first transparent conductive layer 403 may have a refractive index (n) in the range of 1.9-2.0 and an extinction coefficient (k) in the range from 0.02 to 0.03.

To enhance the reflection of light emitting device 400, the present disclosure employs multiple layers with alternating high/low/high refractive indices. Because transparent conductive materials, such as ITO, have been very effective in photovoltaic devices, the present disclosure has met the challenge by utilizing a reflective, but very low absorptive material having a low refractive index relative to ITO.

Some transparent conductive layers, such as those that comprise ITO, have a refractive index of approximately 1.9-2.0. As such, employing the high/low/high refractive indices technique involves utilizing a material layer adjacent thereto which has a characteristically lower refractive index when compared to refractive index of the transparent conductive layer that the material layer is adjacent thereto which will be described in more detail below.

Most notably, the present disclosure provides several materials which may be employed as a low refractive index material layer within light emitting device 400. In particular, silver, gold, or copper may be utilized as low refractive index materials.

For instance, silver may be utilized because of silver's low absorptive properties at very thin geometries (e.g., <30 nm). As such, although it is known in the art that silver material layers have an absorptive property, this property may be negligible for silver material layers having a thickness less than 30 nm.

In some embodiments, low refractive index material layer 404 comprises silver, the refractive index is in the range from 0.1-0.3. Low refractive index material layer 404 may have a refractive index that is less than 1 at a visible range from 380 nm to 780 nm.

In particular, the low refractive index material layer 404 may have a refractive index as low as 0.1. In some embodiments when low refractive index material layer 404 comprises silver, the refractive index (n) and extinction coefficients (k) may be 0.3 and 2.46, respectively.

As previously stated, low refractive index material layer 404 may have a thickness of approximately 30 nm when the layer 404 comprises silver, gold, or copper. However, low refractive index material layer 404 may have a thickness in the range of 5-30 nm. It should be understood by one having ordinary skill in the art that low refractive index material layer 404 may have a very low thickness so long as the material layer 404 is continuous.

Next, a second transparent conductive layer 405 is disposed over low refractive index material layer 404. As shown, second conductive layer 405 may be formed directly upon low refractive index material layer 404. As discussed, the present disclosure may employ a series of layers having alternate high/low/high refractive indices. Accordingly, second transparent conductive layer 405 may comprise a relatively high refractive index when compared to the refractive index of low refractive index material layer 404.

In some embodiments, second transparent conductive layer 405 may have material properties consistent with that of first transparent conductive layer 403. For example, second transparent conductive layer 405 may comprise an ITO material. As such, in some embodiments, second transparent conductive layer 405 may have approximately the same refractive index as that of first transparent conductive layer 403 (e.g., 1.9-2.0).

In some embodiments, second transparent conductive layer 405 may have a thickness that is greater than the thickness of first transparent conductive layer 403. For example, the thickness of second transparent conductive layer 405 may be in the range from 80-200 nm. In some embodiments, second transparent conductive layer 405 has a thickness of approximately 86 nm.

However, the present disclosure is not limited to a light emitting device having a first transparent conductive layer that has material properties consistent with the second transparent conductive layer. Furthermore, light emitting device 400 is not limited to having a first transparent conductive layer 403 with a greater thickness than second transparent conductive layer 405. Accordingly, first transparent conductive layer 403 may have material properties consistent or inconsistent of second transparent conductive layer 405 and may have a thickness greater than or less than the thickness second transparent conductive layer 405.

Accordingly, light emitting device 400 employs a high/low/high refractive indices technique via first transparent conductive layer 403, low refractive index material layer 404, and second transparent conductive layer 405. Most notably, the high/low/high refractive index technique may effectively increase the reflection of the light emitting device 400. For example, the optical reflection may gain 1.5% in reflection to approximately 87% reflection according to some embodiments of the present disclosure.

FIG. 4 further illustrates a light emitting device 400 which includes a reflective layer 406 disposed over second transparent conductive layer 405. As shown, reflective layer 406 may be formed directly upon second transparent conductive layer 405.

Reflective layer 406 may comprise any material and may have any suitable thickness to effectively cause light to reflect therefrom and out of the light emitting device 400. In some embodiments, reflective layer 406 comprises silver (Ag). Reflective layer 406 may have a thickness in the range of 150-300 nm. For example, reflective layer 406 may have a thickness of approximately 200 nm.

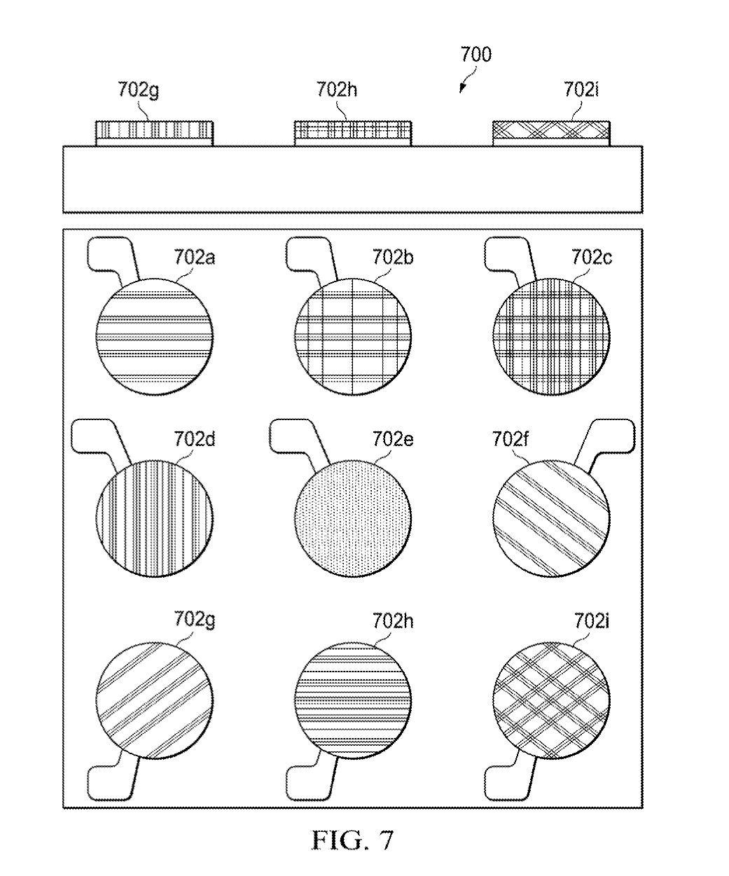

FIG. 5 is a simplified schematic diagram illustrating a three dimensional (3D) plot 500 displaying the reflectance achieved for various thickness values for the first and second transparent conductive layers (see key 501). As shown, the three dimensional plot 500 illustrates peaks and valleys of reflectance values for a light emitting device consistent with the present disclosure. Accordingly, some combinations of first and second transparent conductive layer thickness values yield higher or lower reflectance values than others.

For example, when the thicknesses of first and second transparent conductive layers are 4 nm and 200 nm, respectively, the reflectance of a light emitting device consistent with the present disclosure is approximately 85.8%. Alternatively, when the thicknesses of first and second transparent conductive layers are 4 nm and 86 nm, respectively, the reflectance of the light emitting device consistent with the present disclosure is approximately 87.1%. Notably, light emitting devices consistent with the present disclosure may benefit from a low refractive material layer (e.g., silver) disposed between the first and second transparent conductive layers, of various respective thicknesses, to achieve varying degrees of reflectance.

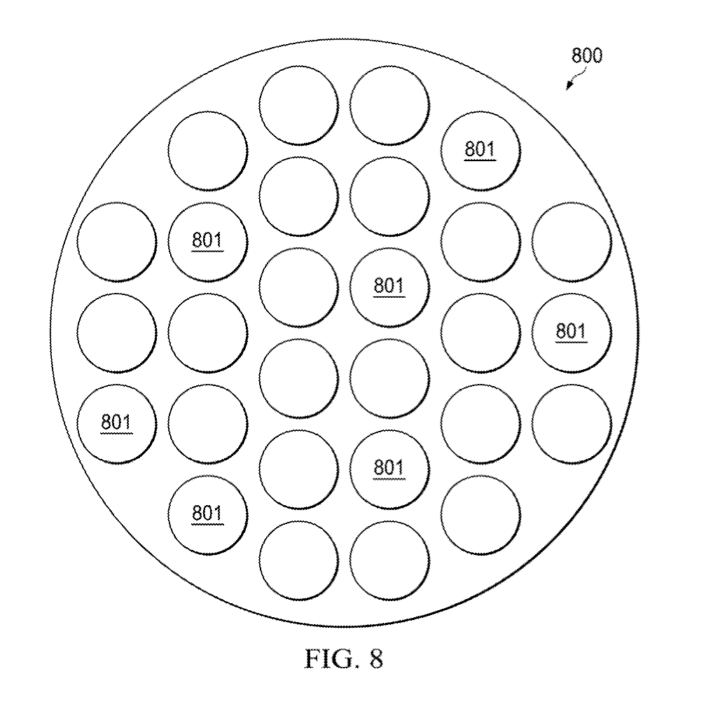

Moving forward, FIG. 6 is a simplified schematic diagram illustrating a combinatorial PVD system 600 according to some embodiments described herein. Details of the combinatorial PVD system 600 shown are described in U.S. patent application Ser. No. 12/027,980 filed on Feb. 7, 2008 claiming priority to U.S. Pat. No. 8,449,678 filed on Feb. 8, 2008 claiming priority to Sep. 5, 2007 which are all herein incorporated by reference for all purposes.

As shown, a substrate 601 is disposed on a substrate support 602. In some embodiments, substrate support 602 has two axes of rotation, 604, 606. In some embodiments, the two axes of rotation 604, 606 may not be aligned which allows different regions on the substrate 601 to be accessed for processing. In addition, the substrate support 602 may be moved in a vertical direction to alter the spacing between the PVD targets and the substrate 601.

In some embodiments, the combinatorial PVD system 600 comprises multiple PVD assemblies 608a-608c configured within a PVD chamber 605. In the figure, three PVD assemblies 608a-608c are present within the PVD chamber 605. One having ordinary skill in the art will appreciate that any number of PVD assemblies 608a-608c within the PVD chambers 605 may be used and that the number of assemblies is limited only by the size of the chamber 605 and each PVD assembly 608a-608c.

Advantageously, each PVD assembly 608a-608c may contain target material(s) 603a-603c to allow a wide range of material and alloy compositions to be deposited and eventually investigated.

Additionally, the combinatorial PVD system 600 may include the capability to perform reactive sputtering utilizing reactive gases such as O₂, NH₃, N₂, etc. The PVD assemblies 608a-608c may be moved in a vertical direction to alter the spacing between the PVD target materials 603a-603c and the substrate 601. In addition, the PVD assemblies 608a-608c may be further operable to tilt to alter an angle of incidence of sputtered material arriving at the surface of the substrate 601.

The combinatorial PVD system 600 may also comprise a process kit shield assembly 610 which may include an aperture 612 used to define site-isolated regions on the substrate 601. In some embodiments, the portion of the process kit shield assembly 610 that includes the aperture 612 may have both rotational and translational capabilities. As such, the combination of substrate support 602 movement, PVD assembly 608a-608c movement, and aperture 612 movement allows processing of various site-isolated regions on a substrate 601. Advantageously, the process parameters amongst the various site-isolated regions on the substrate 601 may be varied in a combinatorial manner.

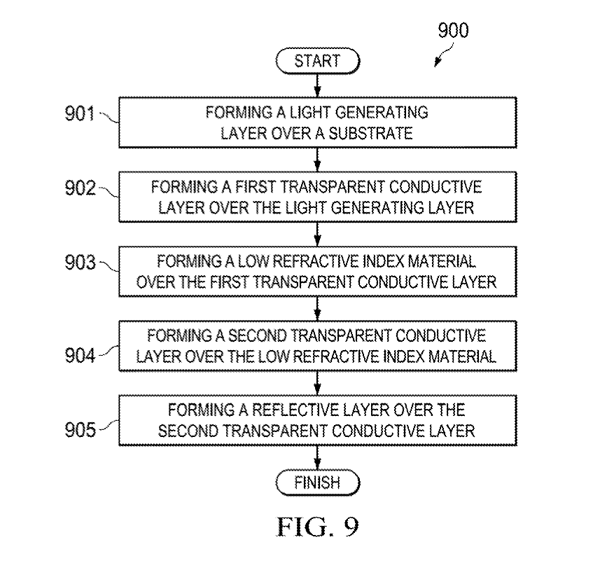

FIG. 7 is a simplified schematic diagram illustrating a substrate 700 that has been processed in a combinatorial manner. Although substrate 700 is illustrated as having a square shape, one having ordinary skill in the art will understand that substrate 700 may have any useful shape such as round, rectangular, etc.

Further, a substrate 700 is shown having nine site-isolated regions, 702a-702i, illustrated thereon. The upper portion of FIG. 7 illustrates a cross-sectional view taken through the three site-isolated regions, 702g-702i, whereas the lower portion of FIG. 7 illustrates a top down view. The shading of the nine site-isolated regions illustrates that the process parameters used to process these regions have been varied in a combinatorial manner. The substrate 700 may be subsequently processed in a conventional or combinatorial manner as discussed earlier with respect to FIG. 2.

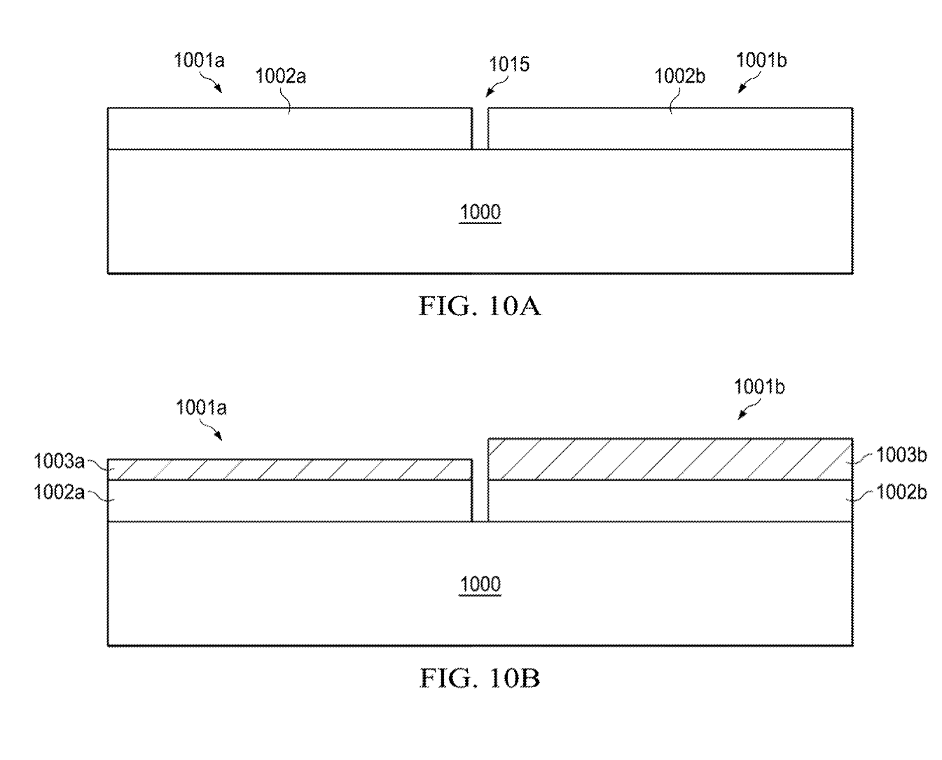

FIG. 8 is a simplified schematic diagram illustrating another example of a substrate 800 having a pattern of site-isolated regions 801. As shown, substrate 800 has twenty-eight site-isolated regions 801 which all may be processed yielding twenty-eight processed site-isolated regions on the substrate 800. As such, in this example, twenty-eight independent experiments may be performed on a single substrate 800.

Substrate 800 may be a wafer having a diameter, such as 300 mm. In some embodiments, substrate 800 may have other shapes, such as square or rectangular. It should be understood that substrate 800 may be a blanket substrate (i.e., having a substantial uniform surface), a coupon (e.g., partial wafer), or even a patterned substrate having predefined regions, such as site-isolated regions 801.

In addition, each site-isolated region 801 may also have a certain shape, such as circular, rectangular, elliptical, or wedge-shaped such that each site-isolated region 801 has a unique shape. A site-isolated region 801 may be, for example, a test structure, single die, multiple die, portion of a die, other defined portion of the substrate 800, or an undefined area of the substrate 800 that may be subsequently defined through processing.

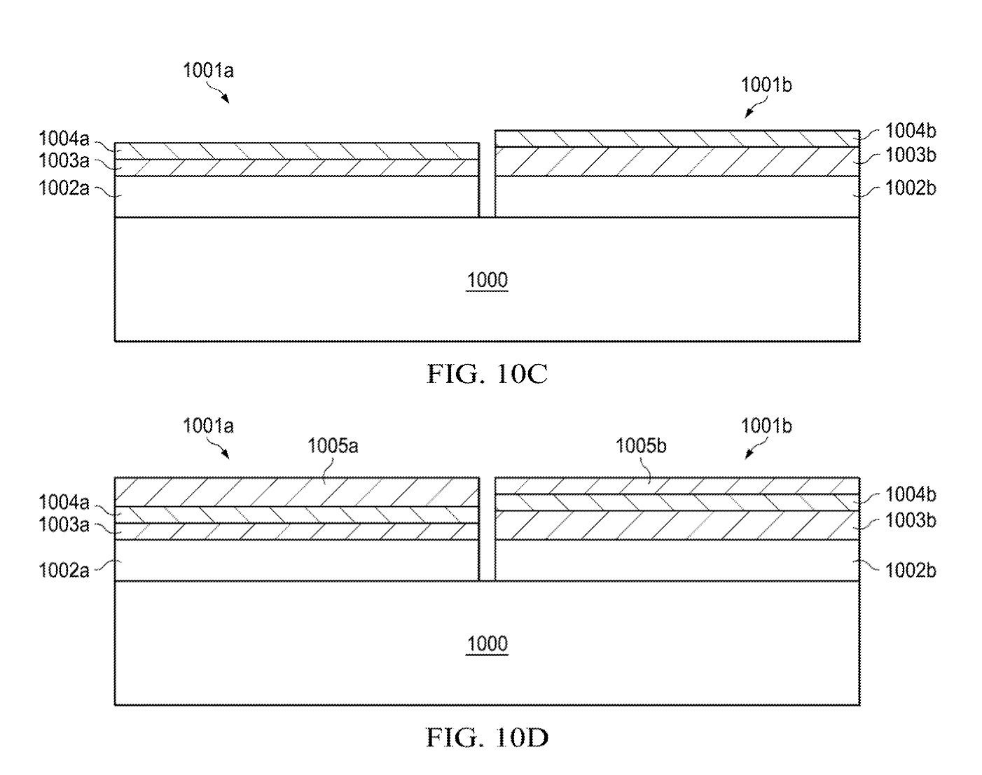

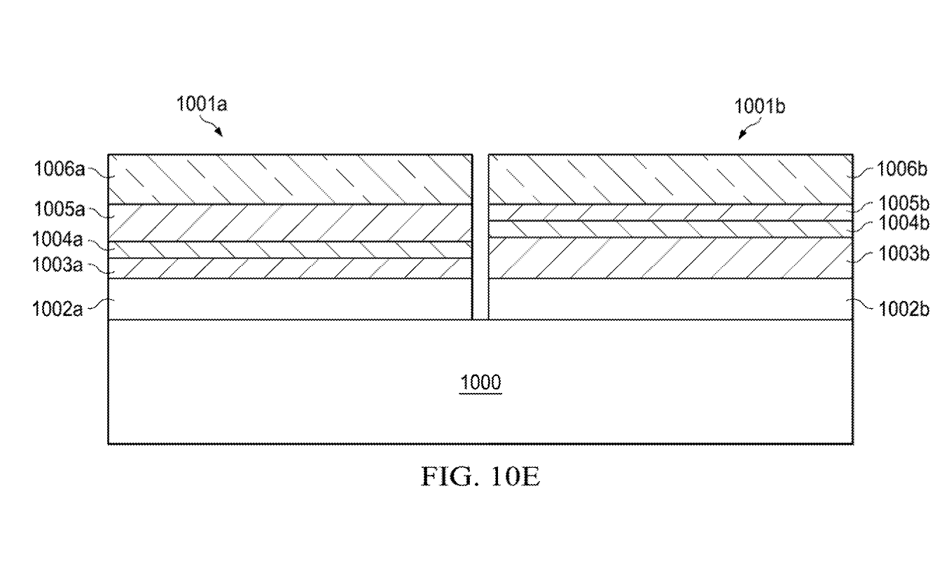

FIG. 9 is a flowchart 900 of a method to form a light emitting device consistent with the present disclosure. Illustrations of an exemplary sequence for forming light emitting devices consistent with the present disclosure are shown in FIGS. 10A-10E while referencing each process block of flowchart 900.

Flowchart 900 begins with block 901—forming a light generating layer over a substrate. Light generating layer may be formed by various methods such as a high temperature chemical vapor deposition (CVD) process.

FIG. 10A illustrates first and second light generating layers 1002a, 1002b formed upon two site-isolated regions 1001a, 1001b of a substrate 1000 separated thereon as depicted by interstitial 1015.

Furthermore, the first light generating layer 1002a and second light generating layer 1002b may comprise different materials. For example, first light generating layer 1002a may comprise p-GaN whereas second light generating layer 1002b may comprise n-GaN. In the figure, the thicknesses of first and second light generating layers 1002a, 1002b are approximately equal. However, in other embodiments, the thicknesses of first and second light generating layers 1002a, 1002b may be different.

Moving forward, FIG. 10B illustrates two alternatives 1003a, 1003b of a first transparent conductive layer disposed above the first and second light generating layers 1002a, 1002b (block 902). First transparent conductive layer 1003a, 1003b may be formed in a combinatorial deposition chamber.

Most notably, transparent conductive layers 1003a, 1003b have different thicknesses as shown in the figure. Therefore, the light emitting devices to be formed (see FIG. 10E) may be evaluated to determine whether the performance is effected by the thickness of the first transparent conductive layers.

First transparent conductive layers 1003a, 1003b may be formed by any suitable method such as a CVD or PVD process. In accordance with some embodiments of the present disclosure, transparent conductive layers 1003a, 1003b are formed within a combinatorial PVD system consistent with the system shown in FIG. 6.

After the first transparent conductive layers 1003a, 1003b are formed, low refractive index material layers 1004a, 1004b are formed thereon (block 903) as shown in FIG. 10C. In some embodiments, low refractive index materials 1004a, 1004b are formed by a PVD process.

Next, consistent with block 904, second transparent conductive layers 1005a, 1005b are formed over the low refractive index material layers 1004a, 1004b as shown in FIG. 10D. Notably, the thickness of transparent conductive layer 1005a is shown to have a greater thickness than the thickness of transparent conductive layer 1005b. The transparent conductive layers 1005a, 1005b may be formed by a CVD or PVD process.

Next, reflective layers 1006a, 1006b are formed (block 905) as shown in FIG. 10E. The reflective layers 1006a, 1006b may be formed by various methods such as a PVD process.

Accordingly, FIG. 10E illustrates two light emitting device experiments carried out on site-isolated regions 1001a, 1001b, which may represent the combinatorial variation of chemicals, target materials, process conditions (i.e., flow rates, pressure, temperature, etc.), surface treatments, etc. Each light emitting device formed may be tested to determine the optimum material and/or processing conditions. Typical tests may comprise measuring reflectivity, light generation, etc.

Methods and apparatuses for combinatorial processing have been described. It will be understood that the descriptions of some embodiments of the present disclosure do not limit the various alternative, modified and equivalent embodiments which may be included within the spirit and scope of the present disclosure as defined by the appended claims. Furthermore, in the detailed description above, numerous specific details are set forth to provide an understanding of various embodiments of the present disclosure. However, some embodiments of the present disclosure may be practiced without these specific details.

What is claimed is:

1. A device, comprising:
a light generating layer formed over a substrate;
a first transparent conductive layer formed over the light generating layer;
a low refractive index material formed over the first transparent conductive layer;
a second transparent conductive layer formed over the low refractive index material; and
a reflective material layer formed over the second transparent conductive layer.

2. The device of claim 1, wherein the light generating layer comprises Gallium Nitride (GaN).

3. The device of claim 1, wherein the first transparent conductive layer comprises indium tin oxide (ITO).

4. The device of claim 1, wherein the low refractive index material comprises silver.

5. The device of claim 1, wherein the low refractive index material has a refractive index that is less than 1.

6. The device of claim 1, wherein the first transparent conductive layer has a refractive index that is greater than 1.5.

7. The device of claim 1, wherein the second transparent conductive layer has a thickness that is greater than the thickness of the first transparent conductive layer.

8. The device of claim 1, wherein the first transparent conductive layer comprises substantially the same material as the second transparent conductive layer.

9. The device of claim 1, wherein the first transparent conductive layer comprises at least one of silver, gold or copper.

10. The device of claim 1, wherein the substrate comprises at least one of sapphire or aluminum oxide.

11. The device of claim 1, wherein the reflective material layer comprises silver.

12. The device of claim 1, wherein the low refractive index material has a thickness that is less than 30 nm.

13. A method of forming light emitting devices in a combinatorial manner, comprising:
forming a first light generating layer over a first site-isolated region of a substrate;
forming a first transparent conductive layer over the first light generating layer;
forming a first low refractive index material over the first transparent conductive layer;
forming a second transparent conductive layer over the first low refractive index material;
forming a first reflective material layer over the second transparent conductive layer;
wherein the first light generating layer, first transparent conductive layer, first low refractive index material, second transparent conductive layer, and first reflective material layer form a first light emitting device on the first site-isolated region;
forming a second light generating layer over a second site-isolated region on the substrate;
forming a third transparent conductive layer over the second light generating layer;
forming a second low refractive index material over the third transparent conductive layer;
forming a fourth transparent conductive layer over the second low refractive index material; and
forming a second reflective material layer over the fourth transparent conductive layer;
wherein the second light generating layer, third transparent conductive layer, second low refractive index material, fourth transparent conductive layer, and second reflective material layer form a second light emitting device on the second site-isolated region; and
evaluating results of the first light emitting device and the second light emitting device.

14. The method of claim 13, wherein evaluating results comprises comparing a physical or electrical characteristic of the first light emitting device and the second light emitting device.

15. The method of claim 13, wherein the first light generating layer and the second light generating layer are formed by a chemical vapor deposition process.

16. The method of claim 13, wherein the first transparent conductive layer, second transparent conductive layer, third transparent conductive layer, and fourth transparent conductive layer are formed by a physical vapor deposition process.

17. The method of claim 13, wherein the first low refractive index material is formed directly upon the first light generating layer.

18. The method of claim 13, wherein the fourth transparent conductive layer is formed directly upon the second low refractive index material.

19. The method of claim 13, wherein the third transparent conductive layer has a thickness that is greater than the thickness of the first transparent conductive layer.

20. The method of claim 13, wherein the thicknesses of the first transparent conductive layer and the second transparent conductive layer are in a range between 5 nm and 30 nm.
